(19) United States
(12) Patent Application Publication
(10) Pub. No.: US 2007/0012251 A1
(43) Pub. Date: Jan. 18, 2007

(54) Seal arrangement with corrosion barrier and method

(76) Inventors: Martin Zucker, Orinda, CA (US); Daniel J. Devine, Los Gatos, CA (US); Rene George, San Jose, CA (US); Josef T. Hoog, Novato, CA (US); Vincent C. Lee, Fremont, CA (US)

Correspondence Address: PRITZKAU PATENT GROUP, LLC, 993 GAPTER ROAD, BOULDER, CO, 80303, US

(21) Appl. No.: 11/478,203

(22) Filed: Jun. 29, 2006

Related U.S. Application Data
(60) Provisional application No. 60/698,205, filed on Jul. 7, 2005.

(51) Int. Cl. C23C 16/00; H01L 21/306

(52) U.S. Cl. 118/733; 156/345.1

(57) ABSTRACT

A guard barrier arrangement is used in an O-ring seal arrangement to limit reactive species in coming into contact with an O-ring. The arrangement is supported in a chamber passage for exposure to the reactive species. An o-ring is compressed so as to peripherally resiliently bias the guard ring arrangement further into the chamber passage configuration toward the chamber interior to limit access of the reactive species to the o-ring. The passage configuration can use a narrowing surface arrangement against which the barrier arrangement is urged. The barrier can include an annular configuration that can change responsive to being biased into the chamber passage configuration.

### CROSS-REFERENCE TO RELATED APPLICATION

This application claims priority to and benefit of U.S. Provisional Patent Application No. 60/698,205 filed on Jul. 7, 2005 (attorney docket no. MAT-22PRO), the entire contents of which are hereby expressly incorporated by reference.

### BACKGROUND

The present invention pertains generally to o-ring seals and specifically to o-ring seals used for sealing corrosive materials.

In a variety of semiconductor process applications (as well as other non-semiconductor related applications), static seals are used to maintain a required seal integrity. Seal integrity is defined by the ability of the seal to maintain several conditions including: (a) a pressure differential in, or in proximity to, the process environment or a required environmental isolation level—a controlled ambient; and/or (b) a required cleanliness level (as defined by the absence of particle generation and/or contamination from o-ring degradation byproducts. One of the critical components of a static seal is the o-ring. O-rings are typically a torus or doughnut shaped component generally molded from elastomers, fluorocarbon or other thermoplastic materials as well as metals. In many applications (including semiconductor fabrication applications), o-rings are very often exposed to reactive species (chemical radicals or ions or neutrals or some combination of these species), high energy and/or high density photons and/or thermal energy that act in such a way as to react with the o-ring causing the o-ring to degrade and fail prematurely. Current industrial solutions to o-ring degradation have included fabricating o-rings from materials that are resistant to attack by reactive species, high energy and/or high-density photons and thermal degradation. This has resulted in O-rings that are extremely expensive and frequently still do not meet required service lifetimes, cleanliness and thermal service temperatures.

The o-ring degradation process typically causes the o-ring material to undergo changes in its chemical bonding that results in one or more failure mechanisms. Failure mechanisms are driven by thermal, chemical and ballistic reactions. O-ring failure expressions include: particulation (generation of particles from a degradation of the basic o-ring material or materials); erosion of the o-ring material and cracking of the polymer component of the o-ring can both result in loss of the seal integrity. An o-ring failure can result from one or more of the previous failure mechanisms. The degradation process can be accelerated by thermal heating of the o-ring material. Heating of the o-ring is frequently a result of direct and/or indirect heating from the process environment. A chemical attack on an o-ring, that results in o-ring erosion, particulation and/or cracking, is frequently referred to as “etching” of the o-ring.

In most applications of o-rings, some portion of the o-ring surface is exposed to an environment that has the capability to degrade the o-ring. For example, the following o-ring/seal concepts depict typical applications for O-rings where some portion of the o-ring is exposed to a hostile environment that has the potential to degrade the seal integrity of the o-ring. The connection between the o-ring gland and the reactive process environment may be small, but reactive species can diffuse into the o-ring gland where they can react with the o-ring, to cause the o-ring to be degraded over time.

FIGS. 7a-c are diagrammatic illustrations of a prior art face-seal o-ring configuration generally indicated by the reference number 10. A reactive process environment 12 is isolated from an ambient environment 14 by using a simple o-ring seal (an o-ring 16 in combination with a simple o-ring groove or gland 18). In most applications where a “face” seal is employed, the seal is a static seal type in that there is no movement of the surfaces that form the face seal gland relative to each other. In FIG. 7a, o-ring 16 is captured between a first component 20 and a second component 22 so as to apply a force 24, that compresses the o-ring, resulting in creation of a seal between the component surfaces that form gland 18. Force 24 may be derived from compressing first component 20 against second component 22.

In FIG. 7b, a part 30 of the o-ring surface shares a path to reactive process environment 12 which contains a reactive species 32. In FIG. 7c, reactive species 32 from the reactive process environment have diffused into the o-ring groove open space and have etched o-ring 16 to the point that the o-ring will soon fail.

The prior art contains a number of other approaches in attempting to protect O-rings from reactive species. For example, one approach attempts to provide a barrier that is intended to limit exposure of the o-ring to the reactive species. A specific example is U.S. Pat. No. 6,245,149, hereinafter the '149 patent. This patent teaches a barrier which relies on a face seal configuration in attempting to protect the o-ring. In this regard, it appears that the barrier is simply inserted adjacent to and inward of the o-ring within the gland or groove that receives the o-ring. Thus, no particular modification of the o-ring gland appears to be necessary except to provide space for the barrier. Both the barrier and the o-ring appear to be independently compressed in a side-by-side relationship between the chamber lid and body, with no mention of contact or cooperation between the o-ring and barrier, responsive to the compressive force. Further, the patent contemplates forming the barrier from a material that is subject at least to length-wise shrinkage and devotes considerable attention to the configuration of the opposing ends of the barrier in having a “slidably coupled” configuration which compensates for lengthwise shrinking of the barrier. The configuration of the '149 patent is considered to pose a considerable challenge with respect to dealing with such complex factors as shrinking barrier elements as well as in being limited to a face seal configuration.

The foregoing examples of the related art and limitations related therewith are intended to be illustrative and not exclusive. Other limitations of the related art will become apparent to those of skill in the art upon a reading of the specification and a study of the drawings.

### SUMMARY OF THE DISCLOSURE

The following embodiments and aspects thereof are described and illustrated in conjunction with systems, tools and methods which are meant to be exemplary and illustrative, not limiting in scope. In various embodiments, one or more of the above-described problems have been reduced or eliminated, while other embodiments are directed to other improvements.

A guard/corrosion barrier and associated method are used in an O-ring seal arrangement to prevent corrosive and/or reactive species from coming in contact with an O-ring. In one aspect of the disclosure, the barrier may be forced into the sealed gap through various configurations. When forced into the sealed gap, the barrier effectively reduces access to the O-ring by reactive species, resulting, for example, in extended O-ring life and/or the ability to use less expensive O-ring materials.

In another aspect of the disclosure, a first chamber portion and a second chamber portion are used in an engaged position for cooperatively defining a chamber interior and for cooperatively defining a passage configuration in the engaged position which leads to the chamber interior from exterior to the chamber arrangement. A sealing arrangement seals the passage configuration in the engaged position. The sealing arrangement includes a guard ring arrangement that is supported in the passage configuration for exposure to the reactive species and an o-ring that is also disposed in the passage configuration adjacent to and immediately outward of the guard ring arrangement in the passage configuration such that the o-ring is compressed so as to peripherally resiliently bias the guard ring arrangement further into the passage configuration toward the chamber interior, thereby limiting passage of the reactive species from the chamber interior to the o-ring.

In another aspect of the disclosure, a chamber includes a first chamber portion having a sealing surface. A second chamber portion includes a tapered surface disposed at an acute angle from the sealing surface of the first chamber portion. A corrosion barrier is disposed against the sealing surface and the tapered surface. An O-ring is disposed against the sealing surface and supported by the first and second chamber portions for applying a biasing force to the corrosion barrier such that the corrosion barrier engages the sealing surface and the tapered surface simultaneously. A corrosive species is located opposite from the O-ring against the corrosion barrier that is corrosive to the O-ring.

In still another aspect of the disclosure, a corrosion barrier and associated method for an O-ring seal arrangement are described. The arrangement includes an annular configuration defining (i) a first surface area adapted to be disposed over a sealing surface of a first chamber portion, (ii) a second surface area adapted to be disposed against a tapered surface of a second chamber portion, the tapered surface being disposed at an acute angle to the sealing surface, (iii) a third surface area adapted to receive a biasing force from an O-ring such that the corrosion barrier engages the sealing surface and the tapered surface simultaneously across the acute angle and the corrosion barrier is formed so as to provide for changing the annular configuration, responsive to the resilient biasing force, in a way which retards a reactive species from reaching an adjacent o-ring. In one feature, the corrosion barrier is formed using an elastic material. In another feature, the corrosion barrier is formed using a material that is substantially rigid with respect to the resilient biasing force and defines a gap having a width that changes responsive to changes in the biasing force to provide for annular movement of the corrosion barrier. In still another feature, the gap is formed as a beveled cut taken in a direction through the corrosion barrier which provides an elongated path of travel for the reactive species through the gap.

In addition to the exemplary aspects and embodiments described above, further aspects and embodiments will become apparent by reference to the drawings and by study of the following descriptions.

### BRIEF DESCRIPTION OF THE DRAWINGS

The present disclosure may be understood by reference to the following detailed description taken in conjunction with the drawings briefly described below.

FIG. 1a is a diagrammatic cross-sectional view, in elevation, showing a chamber arrangement having a sealing arrangement that is configured in accordance with the present invention.

FIG. 1b is a further enlarged, diagrammatic view of a sealing region in the embodiment of FIG. 1a, showing an o-ring with a triangular corrosion barrier.

FIG. 2 is a cross-sectional diagrammatic illustration of another embodiment showing an o-ring with a round corrosion barrier in a sealing arrangement.

FIG. 3 is a cross-sectional diagrammatic illustration of still another embodiment showing an o-ring with a triangular corrosion barrier in a sealing arrangement.

FIG. 4 is a cross-sectional diagrammatic illustration of yet another embodiment showing an o-ring with a triangular corrosion barrier in a gland or face seal.

FIG. 5 is a cross-sectional diagrammatic illustration of an embodiment showing a two piece corrosion barrier arrangement.

FIG. 6 is a diagrammatic side view of the corrosion barrier of FIGS. 1a and 1b, shown here to illustrate further details with respect to its structure.

FIGS. 7a-c are diagrammatic views, in cross-sectional elevation, of a prior art sealing arrangement using an o-ring, shown here to illustrate the potential adverse effects of a reactive species on an o-ring.

### DETAILED DESCRIPTION

The following description is presented to enable one of ordinary skill in the art to make and use the invention and is provided in the context of a patent application and its requirements. Various modifications to the described embodiments will be readily apparent to those skilled in the art and the generic principles herein may be applied to other embodiments. Thus, the present invention is not intended to be limited to the embodiment shown but is to be accorded the wildest scope consistent with the principles and features described herein including alternatives, modifications and equivalents, as defined within the scope of the appended claims. It is noted that the drawings are not to scale and are diagrammatic in nature in a way that is thought to best illustrate features of interest. Further, like reference numbers are applied to like components, whenever practical, throughout the present disclosure. Descriptive terminology such as, for example, upper/lower, right/left, front/rear and the like has been adopted for purposes of enhancing the reader's understanding, with respect to the various views provided in the figures, and is in no way intended as being limiting.

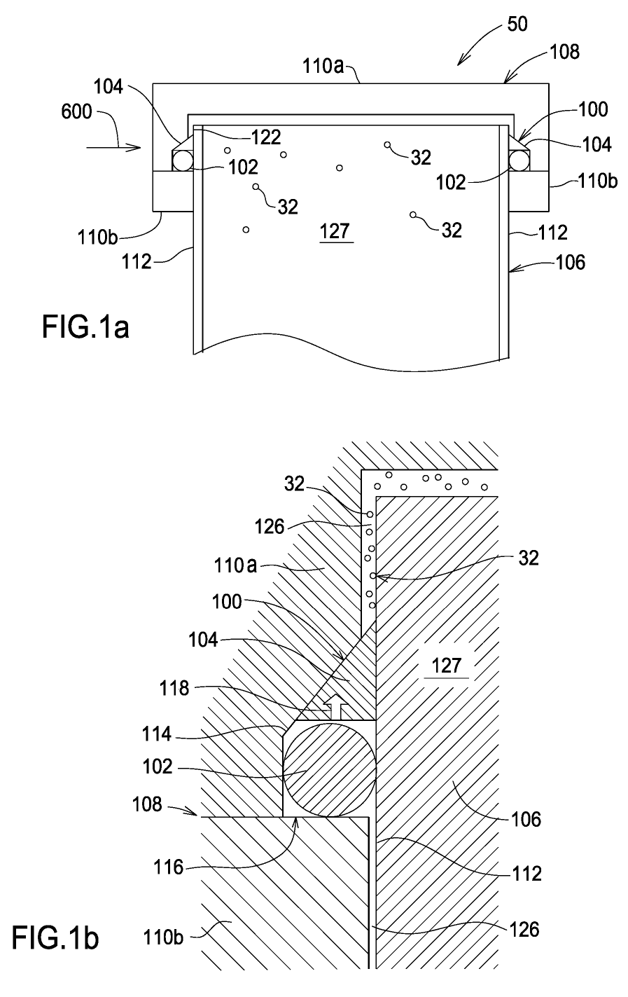

Attention is now immediately directed to the various figures wherein like reference numbers are used to apply to like components whenever practical. FIG. 1a is a diagrammatic cross-sectional view, in elevation, which illustrates a chamber arrangement that is generally indicated by the reference number 50. Chamber arrangement 50 utilizes a sealing arrangement 100. The latter includes an o-ring 102 that is positioned next to a corrosion barrier or guard ring 104 having an annular configuration and, in the present sample, exhibiting a triangular shape in cross section. The chamber arrangement supports sealing arrangement 100 using a first chamber portion 106 and a second chamber portion 108. The first chamber portion can be generally cylindrical in configuration so as to be surrounded by the annular configuration of corrosion barrier 104 and o-ring 102. Second chamber portion 108, in the present example, includes a first chamber member 110a and a second chamber member 110b that is attachable to first chamber member 110a in any suitable manner. The first and second chamber portions are illustrated in an engaged position for purposes of supporting sealing arrangement 100. It is noted that the illustrated configuration is exemplary and that any suitable chamber configuration may be utilized.

Turning now to FIG. 1b, in conjunction with FIG. 1a, the former provides an enlarged partially cut away view of the region of sealing arrangement 100 within chamber arrangement 50 for purposes of illustrating further details of its structure. o-ring 102 and corrosion barrier 104 are in contact with a sealing surface 112 of first chamber portion 106. Corrosion barrier 104 is also in contact with a tapered surface 114 of second chamber portion 108. A biasing surface 116 of second chamber member 110b pushes against o-ring 102, providing a resultant force vector 118 against corrosion barrier 104. It is noted that corrosion barriers throughout this disclosure may be referred to interchangeably as a guard ring, or o-ring guard or corrosion barrier. Corrosive species 32 is thereby limited in contacting o-ring 102. First chamber portion 106 and second chamber portion 108 cooperatively form a passage configuration 126 when assembled into the illustrated engaged position which advantageously forms a circuitous path, although such a path is not a requirement. In the engaged position, the first and second chamber portions cooperate to compress o-ring 102 in a way which peripherally resiliently biases sealing arrangement 100 further into passage configuration 126 in a direction that approaches an interior 127 of the chamber arrangement. That is, when compressed, the o-ring presses against the o-ring guard and the cross-sectional area of the passage configuration or connection between the o-ring gland and the reactive process environment will be minimized. This has the beneficial effect of minimizing the rate at which reactive species can diffuse into the o-ring gland, since the size of the channel/passage connecting the o-ring gland to the chamber interior is reduced. Slowing the rate at which reactive species can diffuse into the o-ring gland reduces the rate at the reactive species will degrade the o-ring, thereby extending the time that the o-ring can be expected to provide the required seal integrity.

Referring to FIG. 1b, passage configuration 126 leads from the location of the o-ring into the chamber interior. The resilient biasing force applied by the o-ring to the guard ring sealing arrangement serves to urge the arrangement into the passage configuration. The passage configuration can take on various shapes in leading to the chamber interior from the o-ring. It is to be understood that all such variations in the shape of the passage configuration are considered to fall within the scope of the present disclosure so long as the passage configuration narrows so as to cause the guard ring to be wedgingly engaged or captured between the first and second chamber portions, responsive to the resilient biasing force that is applied by the o-ring. In this implementation, suitable cross-sectional shapes of the guard ring include, but are not limited to circular, elliptical and triangular configurations.

Sealing arrangement 100 may be used in place of conventional o-ring seal arrangements. Typical applications include vessels such as manufacturing processing equipment, especially vacuum or pressure chambers. Sealing arrangement 100 may be used anywhere a liquid-tight or gas-tight seal is required. Applications may include manufacturing equipment, consumer products, automotive, aerospace, high/low temperature, high pressure, and vacuum applications, among others.

Referring again to FIGS. 1a and 1b, the seal provided by seal arrangement 100 is generally performed by o-ring 102 across passage configuration 126. Any pressure differential between the opposing sides of the seal are maintained by sealing of o-ring 102 against first chamber portion 106 and second chamber portion 108. Potentially corrosive species 32 on the interior side of the seal, such as reactive gasses or liquids, may be prevented from contacting o-ring 102 by corrosion barrier 104.

O-ring 102 may be constructed of material sufficient to affect a seal between the exterior side and chamber interior side 122 of the seal. O-ring 102 may be manufactured from any type of suitable material. In some cases, the material may be selected to give a very good seal but may be slightly or even highly reactive to materials on the chamber interior side of the seal. In other cases, the material may be selected to give adequate sealing performance but may have some resistance to corrosion. Many factors may drive the material selection, including the anticipated length of service, the ease of inspecting and replacing the o-ring, material cost and availability, or any other factor.

Corrosion barrier/guard ring 104 may be manufactured from a material known to be non-reactive to whatever reactive species may exist on the chamber interior side of the seal. The corrosion barrier 104 may act as a plug that mechanically blocks molecules of corrosive species from contacting o-ring 102. In some embodiments, corrosion barrier 104 may be manufactured from a material that undergoes a neutralizing chemical reaction to any corrosive species. In such a case, any reactive species may be substantially mechanically blocked from contacting the o-ring 102 in addition to neutralizing the corrosive species.

In other embodiments, corrosion barrier 104 may be manufactured from a chemically neutral material. Such embodiments may be useful when a chemical reaction between the corrosion barrier 104 and the reactive species may introduce unwanted contaminants into a sealed chamber.

Corrosion barrier 104 is squeezed between the sealing surface 112 and tapered surface 114. Tapered surface 114 may be at an acute angle to sealing surface 112.

Depending on material selection, corrosion barrier 104 may have a tendency to extrude between the first chamber portion 106 and second chamber portion 108 in the direction of the second side 122 of the seal. When tapered surface 114 is constructed to be closer to perpendicular to sealing surface 112, corrosion barrier 104 may be less likely in some situations to extrude. However, less force may be exerted against sealing surface 112 by the corrosion barrier 104. When the tapered surface 114 is more acutely angled to the sealing surface 112, the corrosion barrier may be more likely to extrude, but also may have a larger force exerted against sealing surface 112. Corrosion barrier 104 may be manufactured of elastic material and sized such that corrosion barrier 104 is biased toward second side 122 of the seal during installation and before application of force 118 from o-ring 102.

The selection of appropriate geometries for proper seals may depend on the composition of o-ring 102, the amount of engagement force on the o-ring, the composition of corrosion barrier 104, the tolerances of the various chamber portions, the desired forces exerted amongst the various components of the seal, and other factors.

In the present example, the cross-sectional shape of corrosion barrier 104 is substantially triangular. In some embodiments, corrosion barrier 104 may be any shape whatsoever, including an isosceles triangle, right triangle, any other triangular shape, rectangular, square, circular, oval, diamond, and the like. In some embodiments, corrosion barrier 104 may have a concave side adjacent to o-ring 102. In many cases, the faces of corrosion barrier 104 may be positioned to be substantially flat against sealing surface 112 and tapered surface 114.

The cross-sectional shape of the “o-ring” may be any shape whatsoever, including round, rectangular, elliptical, triangular, X-shape, or any other shape desired.

Second chamber member 110b may be attached by any mechanical method sufficient to provide a biasing force from surface 116. Various geometries and mechanisms may be used by those having ordinary skill in the art in view of this overall disclosure.

In some applications, vacuum grease or other lubricant may be used on the surfaces of o-ring 102 and corrosion barrier 104 to allow some movement between the various components as well as to help affect a seal. Other applications may not require vacuum grease or lubricant, such as when the pressure differential across the seal is low, high temperatures are present, when vacuum grease or lubricant may contaminate the chamber, or for other reasons.

Corrosive species 32 may be any type of reactant that may degrade the performance of the o-ring 102. For example, corrosive species may include chemically reactive radicals, ions, neutrals, or combinations of the same. Additionally, high energy or high density photons may degrade the o-ring performance. High thermal energy and various radiation sources are other examples of potentially corrosive species that may degrade o-ring performance and expedite o-ring failure.

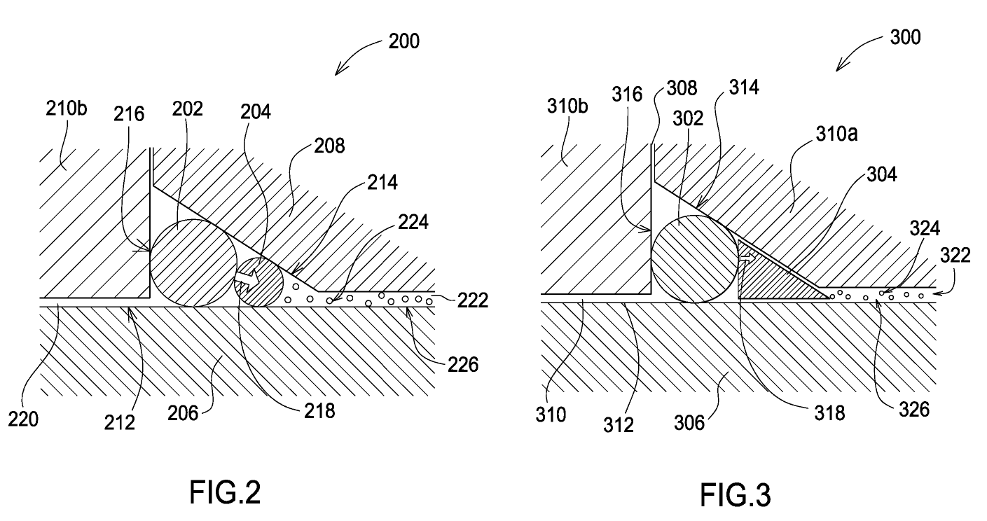

FIG. 2 illustrates another embodiment 200 of a sealing arrangement, in a diagrammatic cross-sectional view, including a corrosion barrier. O-ring 202 is next to a corrosion barrier 204. The seal is contained between first chamber portion 206 and second chamber portion 208. The latter is made up of first chamber member 210a and a second chamber member 210b such that the latter biases o-ring 202 and, thereby, corrosion barrier 204 upon assembly.

O-ring 202 and corrosion barrier 204 are in contact with sealing surface 212 of first chamber portion 206. Corrosion barrier 204 is also in contact with tapered surface 214 of second chamber portion 208. Biasing surface 216 of the third chamber portion 210 pushes against the o-ring 202, providing a resultant force vector 218 against corrosion barrier 204. A corrosive species 224 is limited prevented from contacting o-ring 202 because of corrosion barrier 204. Reactive species 224 may be present within that portion of passage configuration 226 leading from barrier 204 to chamber interior.

Sealing embodiment 200 is an example of the use of a substantially round corrosion barrier 204. The cross-sectional shape of corrosion barrier 204 may be any shape whatsoever. Round shapes may be useful in embodiments where corrosion barrier 204 is manufactured from a material that is pliable or compressible. When subjected to force 218 exerted by o-ring 202, corrosion barrier 204 may deform at least to some extent and flatten against the surfaces it contacts, as it is urged into the passage configuration toward the chamber interior. In some cases, corrosion barrier 204 may elastically deform so that it may return to its original shape when second chamber member 210b is removed. In other cases, corrosion barrier 204 may be selected such that it plastically deforms and does not return to its original shape.

In some seal embodiments, o-ring 202 may be permanently deformed when second chamber member 210b is fully engaged. O-ring 202 may or may not be reusable in those situations. In other embodiments, o-ring 202 may be only slightly deformed or essentially undeformed and o-ring 202 may be reused.

Embodiment 200 illustrates a seal design wherein tapered surface 214 forms a triangular shape. Such a design is sometimes used in o-ring seals where no corrosion barrier is present, however, these designs share the same problems with prior art designs in relatively freely exposing the o-ring to the reactive species. It should be appreciated that the passage arrangement that supports o-ring 202 and corrosion barrier 204 may be constructed having many alternative shapes while still applying the teachings that have been brought to light herein.

FIG. 3 illustrates another embodiment 300 of a sealing arrangement, in a diagrammatic cross-sectional view, including a corrosion barrier. In this example, an o-ring 302 is arranged next to a corrosion barrier 304. The seal is contained between a first chamber portion 306 and a second chamber portion 308. The latter is made up of a first chamber member 310a and a second chamber member 310b which mechanically biases o-ring 302 and corrosion barrier 304 upon assembly.

O-ring 302 and corrosion barrier 304 are in contact with sealing surface 312 of first chamber portion 306. Corrosion barrier 304 is also in contact with tapered surface 314 of second chamber portion 308. Biasing surface 316 of second chamber member 310b pushes against o-ring 302, providing a resultant force vector 318 against corrosion barrier 304. O-ring 302 seals a first side 320 of the passage configuration from a second side 322. A corrosive species 324 is limited or retarded from contacting o-ring 302 because of corrosion barrier 304. Chamber passage 326 is formed when the first chamber portion 306 is in the illustrated engaged position with second chamber portion 308.

Embodiment 300 illustrates a combination of a triangular shaped cavity with a triangular shaped corrosion barrier 304. In some embodiments, corrosion barrier 304 may be fashioned in a tetragon or other shape having two or more straight sides. One or more of the sides of such a corrosion barrier may be oriented substantially parallel to one or more of sealing surface 312 or tapered surface 314.

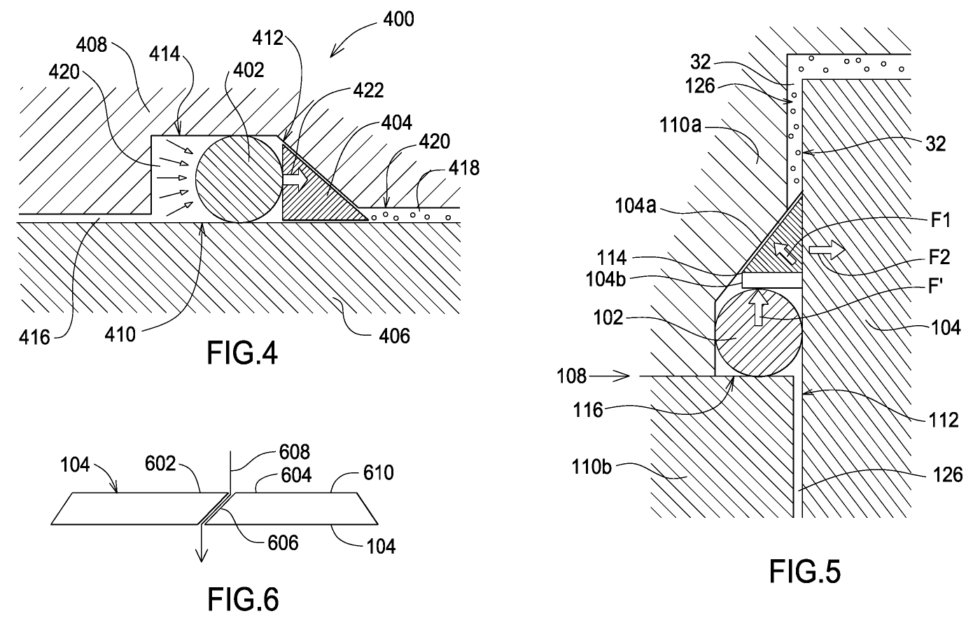

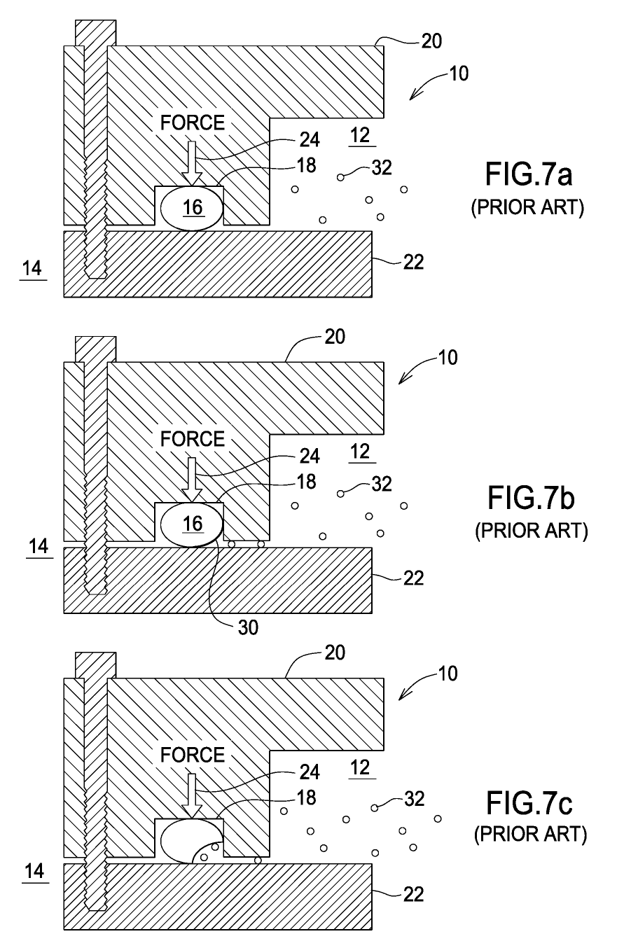

FIG. 4 illustrates an embodiment 400 showing a cross-sectional view of another gland or seat type o-ring seal with a corrosion barrier. O-ring 402 is next to a corrosion barrier 404. The seal is contained between a first chamber portion 406 and a second chamber portion 408.

O-ring 402 and corrosion barrier 404 are in contact with a sealing surface 410 of first chamber portion 406. Corrosion barrier 404 is also in contact with tapered surface 412 of second chamber portion 408. A pressure difference between a high pressure side 416 and a low pressure side 418 causes pressure forces 420 acting on the o-ring to exert a force 422 onto corrosion barrier 404. A corrosive species 420 is at least inhibited in reaching o-ring 402 because of corrosion barrier 404. Passage configuration 426 is formed when first chamber portion 406 is in the illustrated engaged position with second chamber portion 408. O-ring 402 is acted upon by the pressure differential between high pressure side 416 and low pressure side 418 of the seal. In some cases, this embodiment 400 may be used for sliding or rotating seals.

FIG. 5 illustrates a seal embodiment 500, in a diagrammatic cross-sectional view, that is essentially identical to the embodiment of FIGS. 1a and 1b, with the exception that the corrosion barrier arrangement includes two parts. Specifically, an inner o-ring guard member 104a and an outer o-ring guard member 104b are provided. Inner member 104a includes an overall annular configuration and is arranged in passage configuration 126 as described with respect to FIGS. 1a and 1b, having a triangular shaped cross-section. Outer guard ring member 104b, likewise, includes an annular configuration, but with a rectangular cross-section, and is captured between inner guard ring member 104a and o-ring 102. Resilient biasing force is generated by capturing o-ring 102 between the two portions of the chamber arrangement in an engaged position so as to compress the o-ring against the corrosion barrier arrangement. Resilient biasing force F′ is applied from the o-ring through the outer guard ring member to the inner guard ring member and resolves into two resultant reaction forces F1 and F2, as inner guard ring 104a is wedgingly urged into passage configuration 126 leading from the o-ring to the chamber interior. First resultant force F1 is normal to a sloped, first chamber surface (or chamber biasing face) 114 that is engaged by the contact surface of the inner guard ring member. Second resultant force F2 is shown offset with respect to inner guard ring 104a due to illustrative constraints, but is understood to be applied by the inner guard ring member to surface 112. As mentioned above, sloped chamber surface 114 is capable of cooperating with inner guard ring members having alternative configurations, while still causing the inner guard ring member to be wedged into the narrowing passage leading to the chamber interior. Any modification which conforms with this teaching is considered to fall within the scope of the present invention. The slope, in the narrowing portion of the o-ring seal Gland proximate to inner guard ring 104a, is formed between biasing face 114 of the o-ring Gland and seal surface 112. It should be appreciated that this angle can be altered for use in adjusting the resilient biasing force. That is, decreasing the angle will facilitate translation of the o-ring guard into the narrowing passage. Outer member 104b may allow movement between o-ring 102 and the guard ring arrangement during compression and ensure a proper seal. In some cases, outer member 104b may provide some biasing force to hold corrosion barrier 104 in place. Outer member 104b may be constructed to adhere to one of the o-ring 102 or corrosion barrier 104a and slidingly engage the other one of the o-ring or corrosion barrier.

In any embodiment described herein, the o-ring guard and any associated components should be constructed such that the force exerted thereon by a compressed o-ring will be sufficient to insure that the o-ring guard is held or moved into a position that minimizes the connecting channel between the o-ring gland and the reactive process environment. The aforedescribed capability to adjust characteristics of the biasing force is significant, not only for the reason that a nominal biasing force may be available, but because biasing forces can be applied to quite fragile chamber components such as, for example, quartz chamber components such that it may be advantageous to reduce biasing forces by adjusting the angle of the annular sloped chamber surface. Of course, where a wedge-shaped guard member is used, its annular contact surface width can also be adjusted to complement any change in the annular sloped chamber surface.

FIG. 6 is an edge view of o-ring guard 104 of FIG. 1a, taken looking generally at the annular o-ring guard in a direction that is indicated by an arrow 600 in FIG. 1a, with all other components removed for purposes of illustrative clarity. o-ring guard 104 includes a pair of confronting ends 602 and 604 which define a beveled gap 606 therebetween. It should be appreciated that movement of the guard ring into the narrowing passage configuration produces some radial compression of the guard ring. When nominal biasing forces are applied to a substantially rigid guard ring, a solid annular ring may not appropriately engage the surfaces of the first and second chamber portions. Accordingly, gap 606 provides for flexing of the annular configuration of the o-ring guard responsive to even quite nominal forces such as, for example, the resilient biasing force that is generated by an adjacent o-ring while overlapping ends 602 and 604 serve to create a path 608 for reactive species that is generally circuitous in attempting to reach the o-ring. That is, for reactive species entering gap 602 in a direction that is generally normal to an upper edge 610 of the ring, a turn or non-linear path by the reactive species is required to maintain travel in gap 606. In this regard, it should be appreciated that reactive species generally travel along straight lines. Thus, a circuitous path is effective in limiting their travel.

Where inner and outer o-ring guard members are used, as in FIG. 5, each may have a gap that is beveled. The gaps can be offset with respect to their relative positions around the chamber interior to provide an even more circuitous path. One alternative implementation uses a solid aluminum ring as its outer guard ring member 104b, thereby providing sufficient flexibility, and inner guard member 104a with a sloping gap as in FIG. 6. Moreover, even a very soft material can still be configured with a sloped gap, if so desired. With regard to the sloped gap, it is noted that it is not necessary that the confronting ends are in physical contact with one another and that the gap formed between these ends will vary, based on the amount of resilient biasing force that is received from the o-ring, in conjunction with relevant material characteristics. It may be beneficial, however, if the ends just touch, responsive to the resilient biasing force. Again, the overlapping, beveled ends of the o-ring guard serve to provide an extended path for any reactive species that may diffuse into the o-ring gland at the point where the ends of the o-ring guard come together. This overlap also makes it more difficult for ionized reactive species to reach the o-ring as ionized species have a lower probability of traversing an intricate path. It should be appreciated that a sloped gap is not a requirement and any suitable end configuration including square ends may be used in an o-ring guard. Further, a segmented o-ring guard could be provided with multiple gaps.

Referring again to FIG. 6, gap 606 allows guard ring/corrosion barrier 104 to be opened up to fit around a boss, gland, or other obstruction during installation. Further, the gap allows some tolerance to be absorbed between the diameter of the corrosion barrier 104 and any groove into which the corrosion barrier is placed. If corrosion barrier 104 is slightly larger or smaller than the groove, the joint surfaces 604 and 606 may touch and shift slightly, but may not affect the performance of an o-ring in the joint. The present example may be applicable to corrosion barriers that are not flexible enough to stretch over an obstruction during installation. In cases where the corrosion barrier is flexible, a long length of corrosion barrier may be cut to length and installed as described.

While corrosion barrier 104 is annular, the shape, as is likewise the case for any embodiment described herein, may be any shape in which an o-ring seal may be used. For example, substantially square openings may be sealed with O-rings and typically such an installation can include corners manufactured with a specific radius based on the o-ring characteristics. In other examples, serpentine and other shaped o-ring seals may have a corrosion barrier that is shaped to match.

In some embodiments, the first chamber portion may be constructed of a dissimilar material than the second chamber portion. For example, a manufacturing processing chamber may have the first chamber portion manufactured from quartz while the second chamber portion is manufactured from stainless steel. In such cases, the corrosion barrier may be selected to have unequal contact area against the two chamber portions. As mentioned above, the corrosion barrier may be selected to have a large contact area against a brittle quartz surface over which to spread a given load, while having less contact area over a stronger surface such as, for example, a stainless steel surface.

This invention protects O-rings used in static seals from various degradation mechanisms that cause o-ring failure. The use of this invention will result in extended o-ring lifetime. Extended o-ring lifetime can have significant benefits (lower product fabrication costs—reduced fabrication tool downtime and maintenance as well as reduced product cost—and improved product performance and lifetime. Further, the use of this invention can enable the use of o-rings fabricated from less exotic and more inexpensive materials that can also have higher thermal service limits.

The foregoing description of the invention has been presented for purposes of illustration and description. It is not intended to be exhaustive or to limit the invention to the precise form disclosed, and other modifications and variations may be possible in light of the above teachings. Although each of the aforedescribed physical embodiments have been illustrated with various components having particular respective orientations, it should be understood that the present invention may take on a variety of specific configurations with the various components being located in a wide variety of positions and mutual orientations. Furthermore, the methods described herein may be modified in an unlimited number of ways, for example, by reordering the various sequences of which they are made up. Therefore, the present examples are to be considered as illustrative and not restrictive, and the invention is not to be limited to the details given herein but may be modified within the scope of the appended claims.

What is claimed is:

1. A chamber arrangement for use in a processing apparatus for processing at least one substrate using at least one reactive species, said chamber arrangement, comprising:
a first chamber portion and a second chamber portion for use in an engaged position for cooperatively defining a chamber interior in said engaged position and for cooperatively defining a passage configuration in said engaged position which leads to said chamber interior from exterior to the chamber arrangement; and
a sealing arrangement for sealing said passage configuration in the engaged position, said sealing arrangement including (i) a guard ring arrangement that is supported in said passage configuration for exposure to said reactive species and (ii) an o-ring that is also disposed in the passage configuration adjacent to and immediately outward of said guard ring arrangement in said passage configuration such that said o-ring is compressed so as to peripherally resiliently bias the guard ring arrangement further into the passage configuration toward said chamber interior, thereby limiting passage of said reactive species from said chamber interior to the o-ring.

2. The chamber arrangement of claim 1 wherein said first and second chamber portions, in said engaged position, apply a compressive force to said o-ring in a first direction and said o-ring produces a resilient biasing force in a biasing direction, responsive to said compressive force, that is at least approximately normal to said compressive force to resiliently bias the guard ring arrangement further into the passage configuration towards said chamber interior.

3. The chamber arrangement of claim 2 wherein a selected one of the first and second chamber portions defines a biasing face that is sloped with respect to said biasing direction for engaging the guard ring arrangement such that the resilient biasing force is transferred into at least two non-normal directions.

4. The chamber arrangement of claim 3 wherein said guard ring arrangement includes a first guard ring member having a cross section that is triangular in configuration so as to define a contact surface that is sloped with respect to said resilient biasing force and said resilient biasing force causes the contact surface to directly engage the biasing face of the selected one of the first and second chamber portions.

5. The chamber arrangement of claim 4 wherein said first guard ring member includes an overall annular configuration and is formed from an elastic material so as to provide for deformation of the annular configuration responsive to said resilient biasing force.

6. The chamber arrangement of claim 4 wherein said first guard ring member includes an overall annular configuration and is formed from a material that is substantially non-deformable responsive to said resilient biasing force and said annular configuration defines a gap between a pair of confronting ends, said gap having a width that changes responsive to the resilient biasing force to provide for peripheral movement of the first guard ring member.

7. The chamber arrangement of claim 6 wherein said gap is formed in a beveled orientation in a direction through the first guard ring member which provides an elongated path of travel for said reactive species through said passage configuration and within said gap.

8. The chamber arrangement of claim 1 wherein said o-ring produces a resilient biasing force, with said first and second chamber portions in said engaged position, that is applied to the guard ring configuration and cooperates with said passage configuration to wedgingly capture the guard ring configuration therein, responsive to urging by the resilient biasing force.

9. A method for forming a seal in a chamber arrangement that is used in a processing apparatus for processing at least one substrate by exposure to at least one reactive species, said method comprising:
arranging a chamber configuration including a first chamber portion and a second chamber portion for use in an engaged position to cooperatively define a chamber interior and for cooperatively defining a peripheral passage configuration around said chamber interior in said engaged position which leads to said chamber interior from exterior to the chamber configuration; and
providing a sealing arrangement for sealing the passage configuration in the engaged position, said sealing arrangement including (i) a guard ring arrangement that is supported in said passage configuration for exposure to said reactive species and (ii) an o-ring that is also disposed in the passage configuration adjacent to and immediately outward of said guard ring arrangement along said passage configuration with respect to said chamber interior such that said o-ring, in said engaged position, is compressed so as to peripherally resiliently bias the guard ring arrangement further into the passage configuration toward said chamber interior, thereby limiting passage of said reactive species from said chamber interior to the o-ring.

10. The method of claim 9 wherein said first and second chamber portions, in said engaged position, apply a compressive force to said o-ring in a first direction and said o-ring produces a resilient biasing force in a biasing direction, responsive to said compressive force, that is at least approximately normal to said compressive force to resiliently bias the guard ring arrangement further into the passage configuration towards said chamber interior.

11. The method of claim 10 including-using a selected one of the first and second chamber portions to define a biasing face that is sloped with respect to said biasing direction for engaging the guard ring arrangement such that the resilient biasing force is transferred into at least two non-normal directions.

12. The method of claim 11 including providing said guard ring arrangement with a first guard ring member having a cross section that is triangular in configuration so as to define a contact surface that is sloped with respect to said resilient biasing force and said resilient biasing force causes the contact surface to directly engage the biasing face of the selected one of the first and second chamber portions.

13. The method of claim 12 including configuring said first guard ring member with an overall annular configuration that is formed from an elastic material so as to provide for deformation of the annular configuration responsive to said resilient biasing force.

14. The method of claim 12 including configuring said first guard ring member with an overall annular configuration that is formed from a material that is substantially non-deformable responsive to said resilient biasing force and said annular configuration defines a gap between a pair of confronting ends, said gap having a width that changes responsive to the resilient biasing force to provide for peripheral movement of the first guard ring member.

15. The method of claim 14 including forming said gap in a beveled orientation in a direction through the first guard ring member which provides an elongated path of travel for said reactive species through said passage configuration and within said gap.

16. The method of claim 9 wherein said o-ring produces a resilient biasing force, with said first and second chamber portions in said engaged position, that is applied to the guard ring configuration and cooperates with said passage configuration to wedgingly capture the guard ring configuration therein, responsive to urging by the resilient biasing force.

17. A chamber comprising:
a first chamber portion having a sealing surface;
a second chamber portion having a tapered surface disposed at an acute angle from said sealing surface of said first chamber portion;
a corrosion barrier disposed against said sealing surface and said tapered surface;
an O-ring disposed against said sealing surface and supported by the first and second chamber portions for applying a biasing force to said corrosion barrier such that said corrosion barrier engages said sealing surface and said tapered surface simultaneously; and
a corrosive species located opposite from said O-ring against said corrosion barrier, said corrosive species being corrosive to said O-ring.

18. The chamber of claim 17 wherein said O-ring applies said biasing force to said corrosion barrier responsive to contact with the first and second chamber portions.

19. The chamber of claim 17 wherein said O-ring applies said biasing force responsive to said corrosion barrier responsive to a pressure difference across said O-ring.

20. A corrosion barrier for an O-ring seal comprising:
an annular configuration defining (i) a first surface area adapted to be disposed over a sealing surface of a first chamber portion, (ii) a second surface area adapted to be disposed against a tapered surface of a second chamber portion, said tapered surface being disposed at an acute angle to said sealing surface, (iii) a third surface area adapted to receive a biasing force from an O-ring such that said corrosion barrier engages said sealing surface and said tapered surface simultaneously across said acute angle and said corrosion barrier is formed so as to provide for changing the annular configuration, responsive to said resilient biasing force, in a way which retards a reactive species from reaching an adjacent o-ring.

21. The corrosion barrier of claim 20 formed from an elastic material so as to provide for deformation of the annular configuration responsive to said resilient biasing force.

22. The corrosion barrier of claim 20 formed from a material that is substantially non-deformable responsive to said biasing force and said annular configuration defines a gap between a pair of confronting ends, said gap having a width that changes responsive to changes in the biasing force to provide for annular movement of the corrosion barrier.

23. The corrosion barrier of claim 22 wherein said gap is formed as a beveled cut taken in a direction through the corrosion barrier which provides an elongated path of travel for said reactive species through said gap.

24. The corrosion barrier of claim 20 wherein said corrosion barrier comprises a substantially triangular cross-section along said annular configuration.

25. The corrosion barrier of claim 20 wherein said corrosion barrier comprises a substantially circular cross-section along said annular configuration.

26. A method comprising:
assembling a first member and a second member such that an annular tapered surface on said second member is disposed near an annular sealing surface of said first member, said annular tapered surface being disposed at an acute angle with respect to said annular sealing surface;
placing a corrosion barrier, having an annular configuration, such that a first portion of said corrosion barrier is disposed against said annular seal surface and a second portion of said corrosion barrier is disposed against said annular tapered surface;
placing an O-ring against said corrosion barrier;
applying a biasing force to said O-ring such that said O-ring applies an O-ring force to said corrosion barrier, thereby forcing said corrosion barrier against said annular sealing surface and said annular tapered surface substantially simultaneously; and
introducing a corrosive species against said corrosion barrier opposite of said O-ring, said corrosive species being corrosive to said O-ring.

27. The method of claim 26 including supporting said O-ring for compression by said first and second members to apply the biasing force to the O-ring.

28. The method of claim 26 including using a pressure difference across said O-ring to produce said biasing force.

29. The method of claim 26 including configuring said corrosion barrier with a substantially triangular cross-section.

30. The method of claim 26 including configuring said corrosion barrier with a substantially circular cross-section.

31. The method of claim 26 including forming the corrosion barrier from an elastic material so as to provide for deformation of the annular configuration responsive to said resilient biasing force.

32. The method of claim 26 including forming the corrosion barrier from a material that is substantially non-deformable responsive to said biasing force and defining a gap in said annular configuration between a pair of confronting ends, said gap having a width that changes responsive to changes in the biasing force to provide for annular movement of the corrosion barrier.
